(19) United States
(12) Patent Application Publication
(10) Pub. No.: US 2026/0181928 A1
(43) Pub. Date: Jun. 25, 2026

(54) SEMICONDUCTOR PROCESSING FOR BIPOLAR JUNCTION TRANSISTOR (BJT)

(71) Applicant: TEXAS INSTRUMENTS INCORPORATED, Dallas, TX (US)

(72) Inventors: Robert Cassel, Lehi, UT (US); Jonathan Lane, Sandy, UT (US); Hiroshi Yasuda, Plano, TX (US)

(21) Appl. No.: 18/989,449

(22) Filed: Dec. 20, 2024

(51) Int. Cl. H10D 10/60; H01L 21/762; H10D 10/01; H10D 62/13; H10D 62/17; H10D 64/23

(52) U.S. Cl. CPC H10D 10/60; H10D 10/061; H10D 62/137; H10D 62/184; H10D 64/231; H10W 10/0143; H10W 10/17

(57) ABSTRACT

The present disclosure generally relates to semiconductor processing for a bipolar junction transistor (BJT). In an example, a semiconductor device includes a semiconductor substrate, a multi-depth isolation structure in the semiconductor substrate, and a BJT on the semiconductor substrate. The multi-depth isolation structure includes a first isolation portion in the semiconductor substrate and a second isolation portion in the semiconductor substrate. The first isolation portion is to a first depth in the semiconductor substrate. The second isolation portion is to a second depth in the semiconductor substrate. The first depth is deeper in the semiconductor substrate than the second depth. The BJT includes a collector region and a base layer. The collector region is in the semiconductor substrate laterally between the first isolation portion and the second isolation portion. The base layer is on the collector region and over and adjoining the first isolation portion and the second isolation portion.

### BACKGROUND

Integrated circuits may include bipolar junction transistors (BJTs). BJTs may be desirable for their high gain characteristics to satisfy high performance and high current drive needs. Scaling of devices in an integrated circuit to smaller nodes typically requires novel approaches to semiconductor processing for fabricating those devices.

### SUMMARY

An example described herein is a semiconductor device. The semiconductor device includes a semiconductor substrate, a multi-depth isolation structure in the semiconductor substrate, and a bipolar junction transistor (BJT) on the semiconductor substrate. The multi-depth isolation structure includes a first isolation portion in the semiconductor substrate and a second isolation portion in the semiconductor substrate. The first isolation portion is to a first depth in the semiconductor substrate. The second isolation portion is to a second depth in the semiconductor substrate. The first depth is deeper in the semiconductor substrate than the second depth. The BJT includes a collector region and a base layer. The collector region is in the semiconductor substrate laterally between the first isolation portion and the second isolation portion. The base layer is on the collector region and over and adjoining the first isolation portion and the second isolation portion.

Another example is a method. A first trench portion of a trench and a second trench portion of the trench are simultaneously etched to a first depth in a semiconductor substrate and to a second depth in the semiconductor substrate, respectively. The first depth is deeper in the semiconductor substrate than the second depth. The trench is filled with isolation material. The isolation material in the first trench portion forms a first isolation portion of an isolation structure, and the isolation material in the second trench portion forms a second isolation portion of the isolation structure. A BJT is formed on the semiconductor substrate. At least a first portion of the BJT is laterally between the first isolation portion and the second isolation portion. At least a second portion of the BJT is over the first isolation portion and the second isolation portion.

A further example is a method. A mask stack is formed over a semiconductor substrate. A first layer of the mask stack is patterned using a first photolithography process and a first etch process. A second layer of the mask stack is patterned using a second photolithography process and a second etch process. The first layer is over the second layer. The second etch process further removes a portion of the first layer that is exposed using the second photolithography process. A trench is etched in the semiconductor substrate. The trench has a first trench portion and a second trench portion in the semiconductor substrate. The first trench portion corresponds to a first portion of the second layer exposed using the second photolithography process. The second trench portion corresponds to the portion of the first layer exposed using the second photolithography process. The trench is filled with isolation material. The isolation material in the first trench portion forms a first isolation portion, and the isolation material in the second trench portion forms a second isolation portion. A BJT is formed on the semiconductor substrate. At least a first portion of the BJT is laterally between the first isolation portion and the second isolation portion. At least a second portion of the BJT is over the first isolation portion and the second isolation portion.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIGS. 1 through 23 are respective cross-sectional views of a semiconductor device in intermediate stages of manufacturing according to some examples.

FIG. 24 shows layout views of photolithography masks used in the method of manufacturing of FIGS. 1 through 23 and a corresponding layout of a portion of the semiconductor device of FIG. 23 according to some examples.

FIGS. 25 and 26 are respective perspective views of a portion of a semiconductor substrate with a multi-depth isolation structure according to some examples.

FIG. 27 is a cross-sectional view of a semiconductor device according to some examples.

FIG. 28 shows layout views of photolithography masks used in a method of manufacturing the semiconductor device of FIG. 27 and a corresponding layout of a portion of the semiconductor device of FIG. 27 according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing for a bipolar junction transistor (BJT). Some examples include a semiconductor device that includes a multi-depth isolation structure in a semiconductor substrate and a BJT on the semiconductor substrate. The multi-depth isolation structure includes a first isolation portion and a second isolation portion in the semiconductor substrate. The first isolation portion is to a first depth in the semiconductor substrate, and the second portion is to a second depth in the semiconductor substrate. The first depth is deeper in the semiconductor substrate than the second depth. The BJT includes a collector region in the semiconductor substrate laterally between the first isolation portion and the second isolation portion. The BJT further includes a base layer on the collector region and over and adjoining the first isolation portion and the second isolation portion. The multi-depth isolation structure may be fabricated using a mask stack that is patterned using a lithography-etch-lithography-etch (LELE) process. The LELE process may be a partial hardmask LELE process using the mask stack. A trench for the multi-depth isolation structure may be etched to the first depth and the second depth simultaneously using the mask stack.

Implementing such as multi-depth isolation structure may permit implementing a collector region in the semiconductor substrate rather than an epitaxially grown collector layer over the semiconductor substrate. Epitaxially growing a collector layer may result in facets in the collector layer, which may propagate to overlying layers, that may result in performance degradation of a BJT. By obviating an epitaxially grown collector layer, such facets that originate from such growth of the collector layer may be avoided. Also, obviating the collector layer may avoid a photolithography process and etch process used to create an opening through a dielectric layer in which the collector layer is epitaxially grown. Further, the multi-depth isolation structure may permit a relatively low resistance path from the collector region to a collector contact region in the semiconductor substrate. The second isolation portion, which extends to the shallower second depth, may permit a shorter electrical path from the collector region to the collector contact region such that resistance of the electrical path may be relatively low. Other benefits and advantages may be achieved.

Various examples are described subsequently. Although the specific examples may illustrate various aspects of the above generally described features, examples may incorporate any combination of the above generally described features (which are described in more detail in examples below).

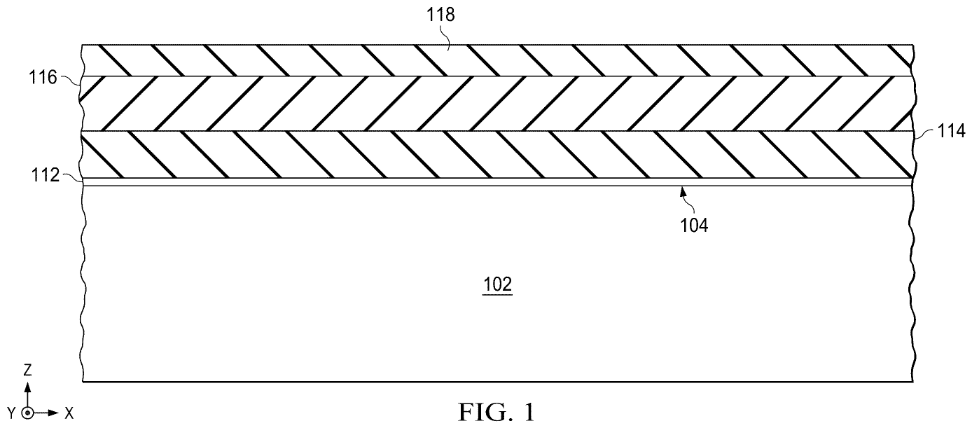

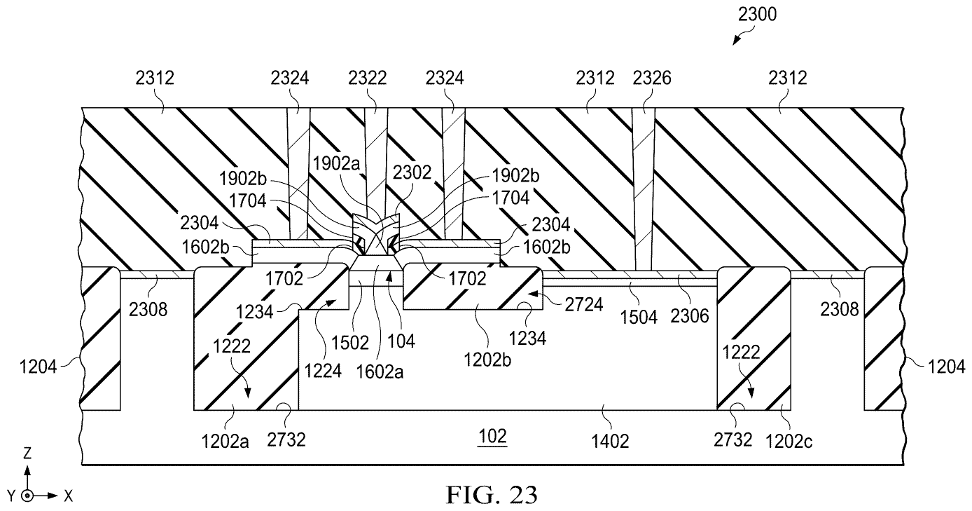

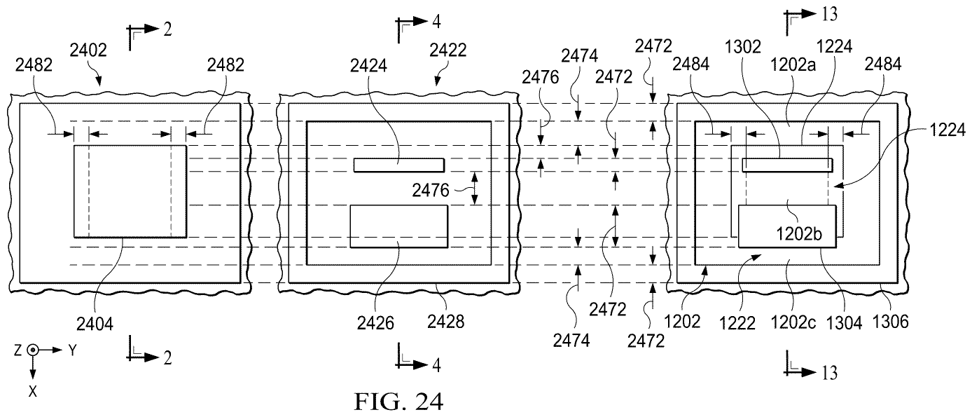

FIGS. 1 through 23 are respective cross-sectional views of a semiconductor device in intermediate stages of manufacturing according to some examples. The method illustrated in these figures forms the semiconductor device 2300 (e.g., including a BJT) of FIG. 23. FIG. 24 illustrates layout views of photolithography masks used in the method of manufacturing of FIGS. 1 through 23 and a corresponding layout of a portion of the semiconductor device 2300 according to some examples. X-Y-Z axes are illustrated in the figures for orientation of the various views.

Referring to FIG. 1, a semiconductor substrate 102 is provided. The semiconductor substrate 102 may be or include a bulk semiconductor substrate, a semiconductor-on-insulator (SOI) substrate, or any other appropriate substrate. The semiconductor substrate 102 may also include a support (or handle) substrate and an epitaxial layer epitaxially grown on the support substrate. In some examples, the semiconductor substrate 102 is or includes a silicon substrate (which may be singulated from a bulk silicon wafer at the conclusion of semiconductor processing). In further examples, the semiconductor substrate 102 includes a silicon substrate with an epitaxial silicon layer grown thereon. The semiconductor substrate 102 is or includes a semiconductor material (e.g., a monocrystalline semiconductor material) in and/or on which devices, such as a BJT (as described subsequently), are formed. In some examples, the semiconductor material is or includes silicon (Si), silicon germanium (SiGe), gallium arsenide (GaAs), gallium nitride (GaN), the like, or a combination thereof. The semiconductor substrate 102 has an upper surface 104 in and/or on which devices (e.g., the BJT) are formed. In some examples, the upper surface 104 is a monocrystalline surface of a monocrystalline semiconductor material. In some examples, the monocrystalline semiconductor material is silicon, and the upper surface 104 is a (100) plane of monocrystalline silicon. In the illustrated example, the semiconductor material of the semiconductor substrate 102 is p-type doped with a p-type dopant. In some examples, the semiconductor substrate 102 is p-type doped with a p-type dopant (e.g., boron (B)) with a concentration in a range from 1×10¹⁴ cm⁻³ to 1×10¹⁵ cm⁻³. Another dopant type and/or other doping concentrations may be implemented.

A mask stack is formed on and over the upper surface 104 of the semiconductor substrate 102. The mask stack includes a first mask layer 112, a second mask layer 114, a third mask layer 116, and a fourth mask layer 118. The first mask layer 112 is formed on and over the upper surface 104 of the semiconductor substrate 102. The first mask layer 112 is capable of being etched selectively relative to the semiconductor substrate 102 and an overlying layer. In some examples, the first mask layer 112 may be silicon oxide formed using oxidation, such as by in situ steam generation (ISSG) oxidation or another oxidation process. In other examples, another material and/or another deposition process may be used to form the first mask layer 112.

The second mask layer 114 is formed on and over the first mask layer 112. The second mask layer 114 is capable of being etched selectively relative to the first mask layer 112 and an overlying layer. In some examples, the second mask layer 114 may be simultaneously etched with the semiconductor substrate 102 while maintaining etch selectivity with the first mask layer 112. For example, the semiconductor material of the semiconductor substrate 102 and the second mask layer 114 may be or include a same material (e.g., silicon). In some examples, the second mask layer 114 may be polycrystalline silicon (polysilicon) formed using any appropriate deposition process, such as chemical vapor deposition (CVD) or the like. In other examples, another material and/or another deposition process may be used to form the second mask layer 114.

The third mask layer 116 is formed on and over the second mask layer 114. The third mask layer 116 is capable of being etched selectively relative to the second mask layer 114 and an overlying layer. The third mask layer 116 may also be a same material as the first mask layer 112 such that the third mask layer 116 and the first mask layer 112 may be etched simultaneously by a selective etch. In some examples, the third mask layer 116 may be silicon oxide (e.g., a tetraethyl orthosilicate (TEOS) oxide) formed using any appropriate deposition process, such as CVD or the like. In other examples, another material and/or another deposition process may be used to form the third mask layer 116.

The fourth mask layer 118 is formed on and over the third mask layer 116. The fourth mask layer 118 is capable of being etched selectively relative to the third mask layer 116. In some examples, the fourth mask layer 118 may be silicon nitride formed using any appropriate deposition process, such as CVD or the like. In other examples, another material and/or another deposition process may be used to form the fourth mask layer 118.

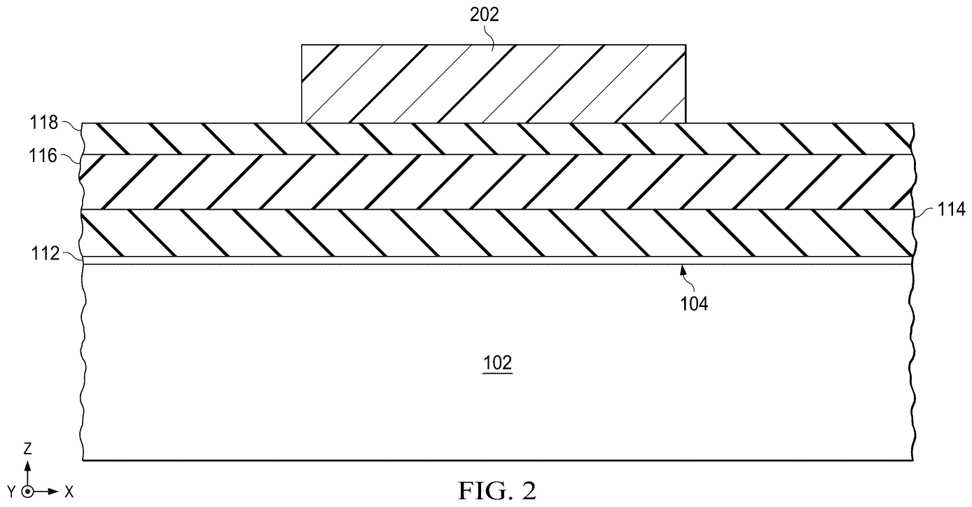

Referring to FIG. 2, a patterned photoresist 202 is formed on and over the fourth mask layer 118. A photoresist may be deposited (e.g., by spin-on) on the fourth mask layer 118 and patterned into the patterned photoresist 202 by using photolithography. The photoresist 202 may be patterned using the photolithography mask 2402 of FIG. 24. The photolithography mask 2402 includes an opaque area 2404, which corresponds to the patterned photoresist 202. Other areas of the photolithography mask 2402 are transparent. The cross-section illustrated by FIG. 2 corresponds to cross-section 2-2 in FIG. 24. The photolithography mask 2402 is described and illustrated in the context of patterning a positive tone photoresist. The photolithography mask 2402 may be modified (e.g., opaque to transparent, and vice versa) to be used to pattern a negative tone photoresist. As described subsequently, where the patterned photoresist 202 remains may correspond to areas where a multi-depth isolation structure (e.g., a multi-depth shallow trench isolation (STI) structure) is to be formed in the semiconductor substrate 102 to a shallower depth than a deeper depth of the multi-depth isolation structure.

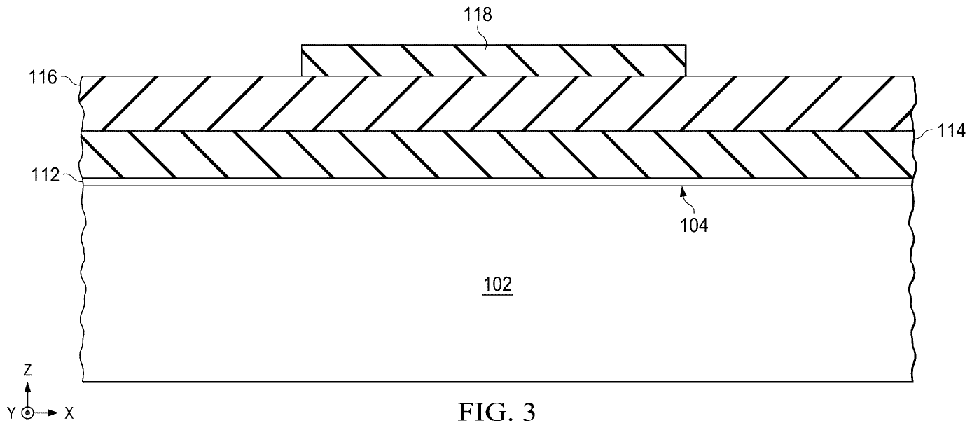

Referring to FIG. 3, the fourth mask layer 118 is selectively etched. Using the patterned photoresist 202 as a mask, the fourth mask layer 118 is selectively etched to remove portions of the fourth mask layer 118 exposed by the patterned photoresist 202. The fourth mask layer 118 that was under the patterned photoresist 202 remains over the third mask layer 116. The etch may be any appropriate etch process, such as an anisotropic etch like a reactive ion etch (RIE). Any remaining patterned photoresist 202 may be removed, such as by an ashing process, after the etch process.

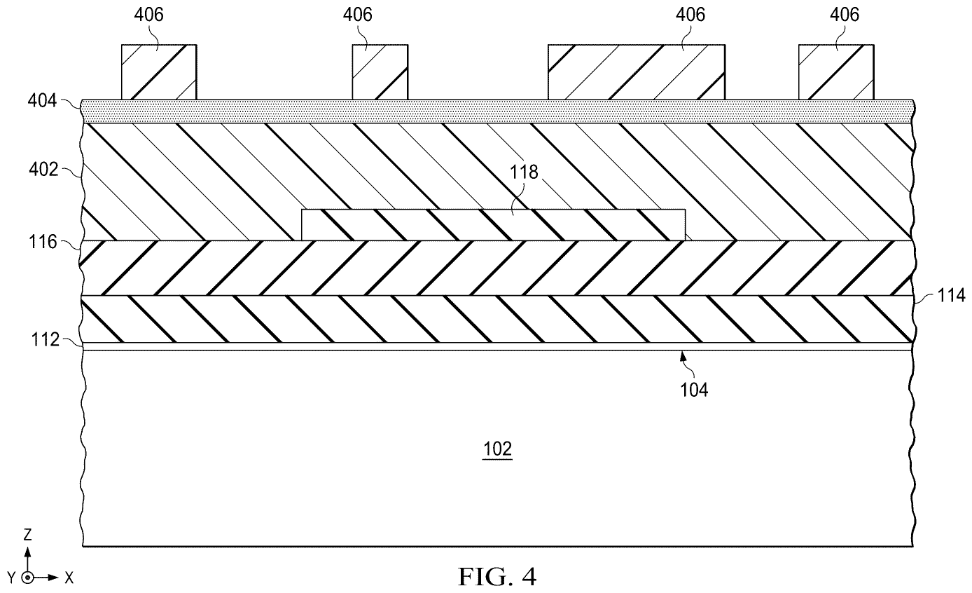

Referring FIG. 4, a multi-layer resist (MLR) structure is formed over the third mask layer 116 and the fourth mask layer 118. The MLR structure includes an underlayer 402 on and over the third mask layer 116 and the fourth mask layer 118, an anti-reflection coating (ARC) layer 404 on and over the underlayer 402, and a patterned photoresist 406 on and over the ARC layer 404. The underlayer 402 may be or include an organic hardmask material used in, e.g., a tri-layer patterning scheme or the like. The underlayer 402 may be formed by using spin-on or the like. The underlayer 402 may provide a planarized surface over which a photoresist is to be formed. The underlayer 402 may be planarized by a chemical mechanical polish (CMP) in some examples. The ARC layer 404 may be or include inorganic hardmask materials used in, e.g., a tri-layer patterning scheme or the like. The ARC layer 404 may be formed by using spin-on or the like.

A photoresist may be deposited (e.g., by spin-on) on the ARC layer 404 and patterned into the patterned photoresist 406 by using photolithography. The photoresist 406 may be patterned using the photolithography mask 2422 of FIG. 24. The photolithography mask 2422 includes opaque areas 2424, 2426, 2428, which correspond to the patterned photoresist 406. Other areas of the photolithography mask 2422 are transparent, which corresponds to openings through the patterned photoresist 406. The cross-section illustrated by FIG. 4 corresponds to cross-section 4-4 in FIG. 24. The photolithography mask 2422 is described and illustrated in the context of patterning a positive tone photoresist. The photolithography mask 2422 may be modified (e.g., opaque to transparent, and vice versa) to be used to pattern a negative tone photoresist. As described subsequently, an opening through the patterned photoresist 406 corresponds to an area where the multi-depth isolation structure is to be formed in the semiconductor substrate 102. Where a portion of an opening through the patterned photoresist 406 corresponds with where the fourth mask layer 118 remains, the multi-depth isolation structure is to be formed in the semiconductor substrate 102 to the shallower depth relative to a deeper depth of the multi-depth isolation structure. Where a portion of the opening through the patterned photoresist 406 does not correspond with where the fourth mask layer 118 remains (e.g., where the fourth mask layer 118 has been removed), the multi-depth isolation structure is to be formed in the semiconductor substrate 102 to the deeper depth.

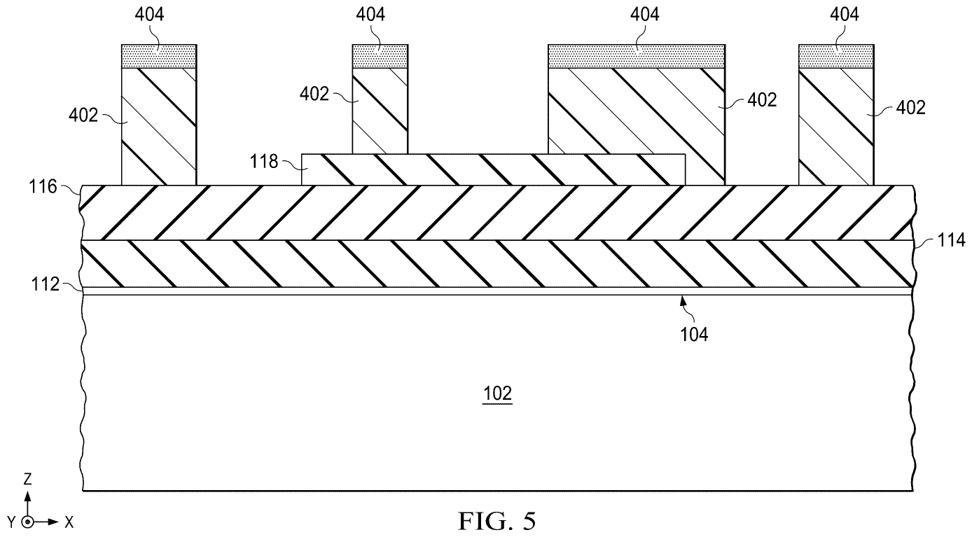

Referring to FIG. 5, the ARC layer 404 and the underlayer 402 are etched. Using the patterned photoresist 406 as a mask, the ARC layer 404 and the underlayer 402 are etched to remove portions of the ARC layer 404 and the underlayer 402 exposed through the patterned photoresist 406. The pattern of the patterned photoresist 406 is transferred into the ARC layer 404 and the underlayer 402 by the etch. The etch may be any appropriate etch process, such as an anisotropic etch like an RIE. As illustrated, the etch process may consume the patterned photoresist 406. In other examples, any remaining patterned photoresist 406 may be removed, such as by an ashing process, after the etch process.

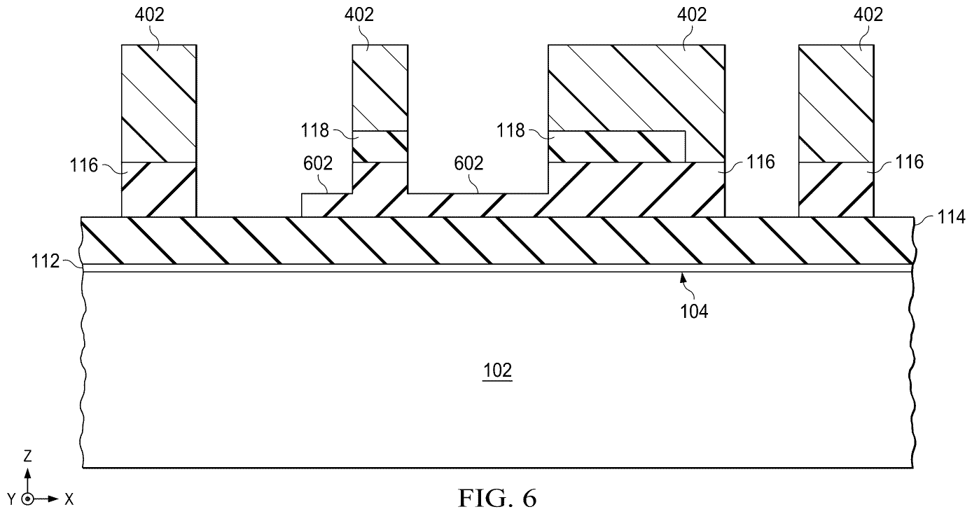

Referring to FIG. 6, an etch process is performed. The etch process is a non-selective etch process relative to the fourth mask layer 118 and the third mask layer 116 and may be a timed etch. The etch process etches portions of the fourth mask layer 118 and third mask layer 116 exposed by the openings through the MLR structure (e.g., the underlayer 402 and ARC layer 404). The etch process etches through the third mask layer 116 and exposes the second mask layer 114, where the third mask layer 116 is uncovered by the fourth mask layer 118 and uncovered by the MLR structure. Moreover, the etch process etches through the fourth mask layer 118 and into the third mask layer 116, such that a portion 602 of the third mask layer 116 remains, where a portion of the fourth mask layer 118 covers the third mask layer 116 and is exposed through an opening through the MLR structure (e.g., the underlayer 402 and ARC layer 404). The etch process may consume any remaining patterned photoresist 406, the ARC layer 404 (as illustrated), and a portion of the underlayer 402 (not illustrated). The non-selective etch process may be any appropriate etch process, such as an anisotropic etch like an RIE.

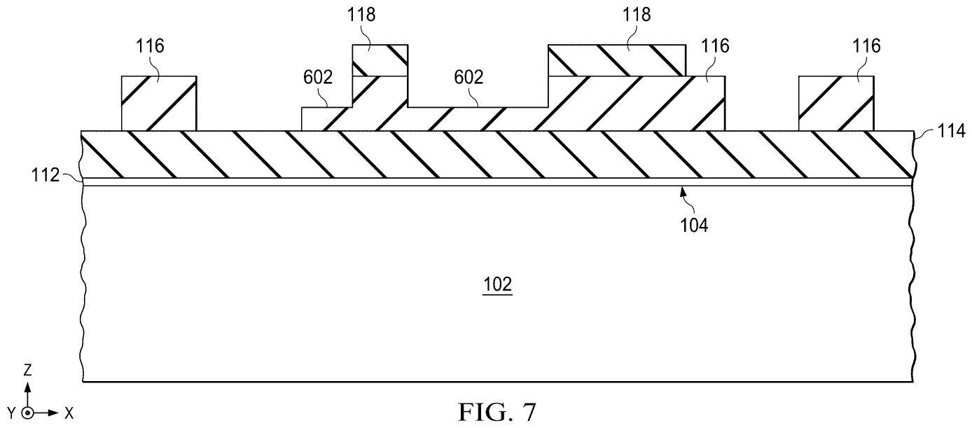

Referring to FIG. 7, any remaining MLR structure (e.g., patterned photoresist 406, ARC layer 404, and underlayer 402) is removed. The MLR structure may be removed using an ashing process.

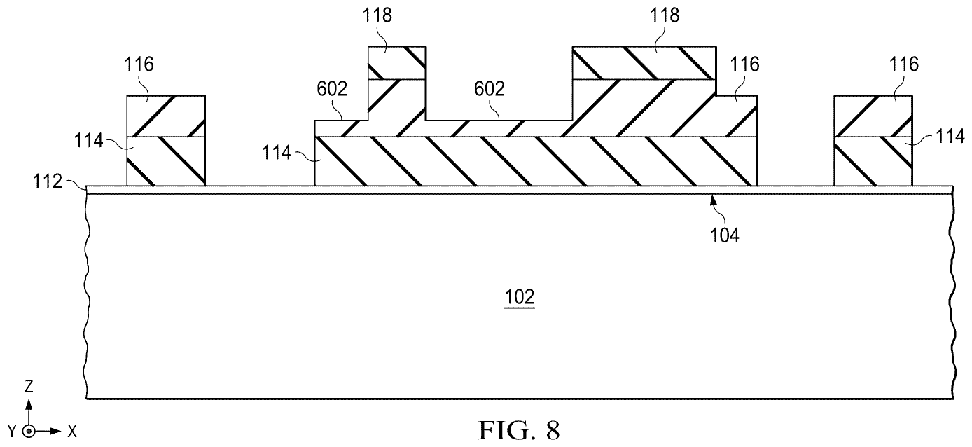

Referring to FIG. 8, the second mask layer 114 is etched. A selective etch process is performed to etch the second mask layer 114 using the third mask layer 116 as a mask. Portions of the second mask layer 114 exposed by openings through the third mask layer 116 are etched to expose the first mask layer 112 and form the second mask layer 114 with corresponding openings. In some examples, as illustrated, the selective etch process may partially consume some exposed portions of the third mask layer 116 to form a thinner third mask layer 116 where exposed, including thinner portions 602 of the third mask layer 116. The selective etch process may be any appropriate etch process, such as an anisotropic etch like an RIE.

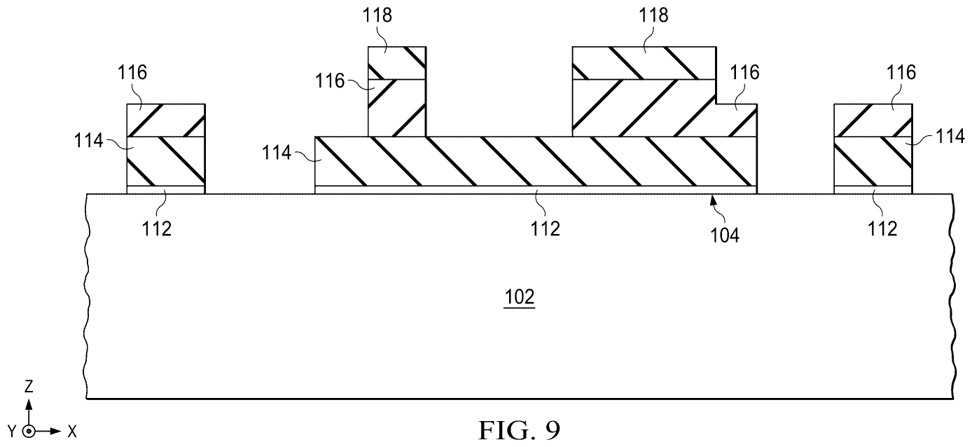

Referring to FIG. 9, the first mask layer 112 and the third mask layer 116 are etched. A selective etch process is performed to etch the first mask layer 112 and the third mask layer 116 using the fourth mask layer 118 and the second mask layer 114 as respective masks. Portions of the first mask layer 112 exposed by the openings through the second mask layer 114 are etched to expose the upper surface 104 of the semiconductor substrate 102 and form the first mask layer 112 with corresponding openings. Further, portions (e.g., portions 602) of the third mask layer 116 uncovered by the fourth mask layer 118 are etched, which may expose the second mask layer 114 and form the third mask layer 116 with a laterally expanded opening (e.g., the far left portion of the opening through the third mask layer 116 that exposes a portion of the second mask layer 114). The selective etch process may be any appropriate etch process, such as an anisotropic etch like an RIE.

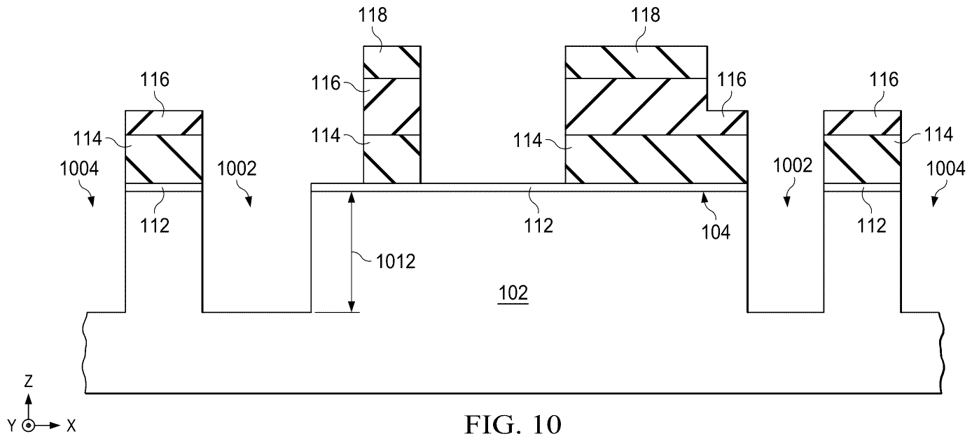

Referring to FIG. 10, a first substrate etch process is performed to form intermediate trenches 1002, 1004 in the semiconductor substrate 102. The first substrate etch process etches portions of the semiconductor substrate 102 exposed through the second mask layer 114 and the first mask layer 112. The intermediate trenches 1002, 1004 are etched to an intermediate depth 1012 from the upper surface 104 of the semiconductor substrate 102. Additionally, the first substrate etch process etches and removes portions of the second mask layer 114 exposed by an opening through the third mask layer 116 (e.g., when the semiconductor material of the semiconductor substrate 102 is silicon and the second mask layer 114 is polysilicon) and may etch and reduce a thickness of exposed portions of the third mask layer 116. The first substrate etch process may be any appropriate etch process, such as an anisotropic etch like an RIE.

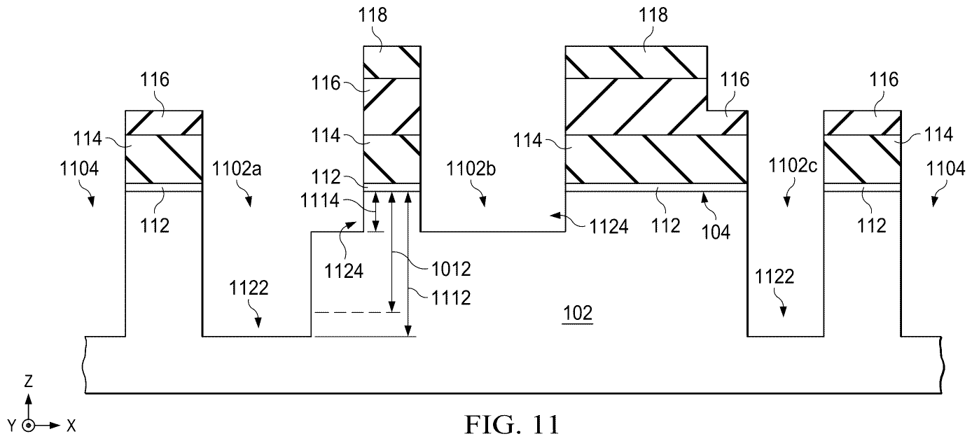

Referring to FIG. 11, the first mask layer 112 is etched where the first mask layer 112 is exposed—e.g., uncovered by the second mask layer 114. A selective etch process is performed to etch the first mask layer 112 using the third mask layer 116 and the second mask layer 114 as a mask. Portions of the first mask layer 112 exposed by an opening through the third mask layer 116 and the second mask layer 114 (e.g., portions of the first mask layer 112 uncovered by the second mask layer 114) are etched to expose the upper surface 104 of the semiconductor substrate 102. In some examples, a portion of the opening through the first mask layer 112 may be laterally expanded as a result (e.g., a portion of the opening through the first mask layer 112 corresponding to the first portion 1102a of the multi-depth trench 1102).

A second substrate etch process is performed to form a multi-depth trench 1102 and a single-depth trench(es) 1104 in the semiconductor substrate 102. For ease of reference, the multi-depth trench 1102 includes a first portion 1102a, a second portion 1102b, and a third portion 1102c. The second substrate etch process etches exposed portions of the semiconductor substrate 102 exposed through the first mask layer 112, second mask layer 114, and third mask layer 116. The multi-depth trench 1102 is etched simultaneously to a first depth 1112 from the upper surface 104 of the semiconductor substrate 102 and a second depth 1114 from the upper surface 104 of the semiconductor substrate 102. The first depth 1112 is deeper from the upper surface 104 of the semiconductor substrate 102 than the intermediate depth 1012. The first depth 1112 is also deeper than the second depth 1114. The intermediate depth 1012 may be deeper than the second depth 1114. The single-depth trench(es) 1104 is etched to the first depth 1112 from the upper surface 104 of the semiconductor substrate 102. The second substrate etch process further etches the intermediate trenches 1002, 1004 to extend that trench to the first depth 1112 and to etch any additionally exposed areas of the semiconductor substrate 102 to form respective trenches (or portions thereof) to the second depth 1114. As illustrated, the multi-depth trench 1102 includes a first depth portion 1122 that extends to the first depth 1112 and a second depth portion 1124 that extends to the second depth 1114. The first portion 1102a includes part of the first depth portion 1122 and part of the second depth portion 1124; the second portion 1102b includes part of the second depth portion 1124; and the third portion 1102c includes part of the first depth portion 1122.

Additionally, the selective etch process to etch the first mask layer 112 and/or the second substrate etch process may etch and reduce a thickness of exposed portions of the third mask layer 116. Each of these etch processes may be any appropriate etch process, such as an anisotropic etch like an RIE.

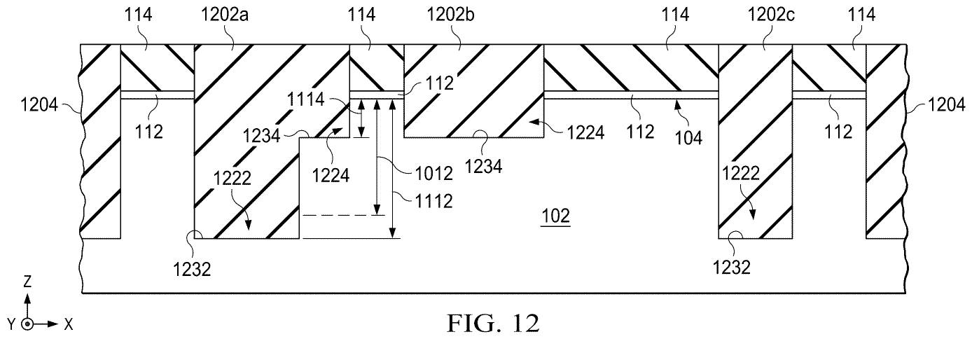

Referring to FIG. 12, a multi-depth isolation structure 1202 and a single-depth isolation structure(s) 1204 are formed in the multi-depth trench 1102 and single-depth trench 1104, respectively, in the semiconductor substrate 102. For ease of reference, the multi-depth isolation structure 1202 includes a first portion 1202a (in the first portion 1102a of the multi-depth trench 1102), a second portion 1202b (in the second portion 1102b of the multi-depth trench 1102), and a third portion 1202c (in the third portion 1102c of the multi-depth trench 1102). In the illustrated example, the isolation structures 1202, 1204 are STI structures extending from the upper surface 104 of the semiconductor substrate 102 into the semiconductor substrate 102. The isolation structures 1202, 1204 may each include, for example, a liner layer, such as including silicon oxide or silicon nitride, conformally along surfaces of a respective trench 1102, 1104 and a fill isolation material, such as silicon oxide, over and on the liner layer. The liner layer may be conformally deposited in the trenches 1102, 1104 and over the mask layers 112, 114, 116, 118, such as by plasma enhanced CVD (PECVD), or formed on surfaces of the trenches 1102, 1104 (e.g., by an oxidation process), and the fill isolation material may be deposited over the liner layer, such as by high aspect ratio CVD (HAR-CVD), flowable CVD (FCVD), or the like. A densification process, such as an anneal process, may be performed to densify the fill isolation material. A CMP is performed to remove excess fill isolation material and liner layer and to remove the third mask layer 116 and the fourth mask layer 118.

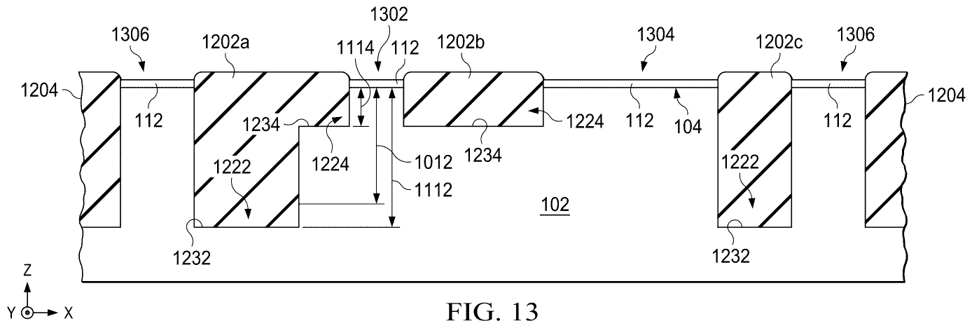

Referring to FIG. 13, the second mask layer 114 is removed by an etch process selective to the material of the second mask layer 114 (e.g., preferentially etching or removing the material of the second mask layer 114 over other materials), which may be a wet etch process. The etch process may remove an upper portion of the isolation structures 1202, 1204 and round upper corners at or above the upper surface 104 of the semiconductor substrate 102. Additional development of further upper portions of the isolation structures 1202, 1204 by subsequent processing (e.g., etch processes, cleaning processes, and/or the like) may occur, although such development may not be explicitly described.

The multi-depth isolation structure 1202 includes a first depth portion 1222 (e.g., in the first depth portion 1122 of the multi-depth trench 1102) that extends to the first depth 1112 and a second depth portion 1224 (e.g., in the second depth portion 1124 of the multi-depth trench 1102) that extends to the second depth 1114. The first depth portion 1222 has a bottom surface 1232 at the first depth 1112. The second depth portion 1224 has a bottom surface 1234 at the second depth 1114. In the illustrated example, the first portion 1202a of the multi-depth isolation structure 1202 includes a part of the first depth portion 1222 and a part of the second depth portion 1224; the second portion 1202b of the multi-depth isolation structure 1202 includes a part of the second depth portion 1224; and the third portion 1202c of the multi-depth isolation structure 1202 includes a part of the first depth portion 1222.

FIG. 24 further shows a layout view (e.g., a composite view with the photolithography mask 2422 laterally relative to the photolithography mask 2402) of the multi-depth isolation structure 1202 and active areas of the semiconductor substrate 102. The layout of the multi-depth isolation structure 1202 shows a cross-section 13-13 that is the cross-section of FIG. 13 (and subsequent figures, including FIG. 23). The multi-depth isolation structure 1202 laterally defines areas (e.g., active areas 1302, 1304) of the upper surface 104 of the semiconductor substrate 102 on which the BJT is to be formed. The multi-depth isolation structure 1202 laterally encircles or encompasses the active areas 1302, 1304 of the upper surface 104 of the semiconductor substrate 102 on which the BJT is to be formed. In the illustrated example, the second depth portion 1224 laterally encircles or encompasses active area 1302, and the first depth portion 1222 laterally encircles or encompasses the second depth portion 1224 and the active areas 1302, 1304. The active area 1302 is where a collector region (e.g., collector region 1502, as described subsequently) is formed, and the active area 1304 is where a collector contact region (e.g., collector contact region 1504, as described subsequently) is formed. As indicated subsequently, an active portion (e.g., a base layer) of the BJT extends laterally beyond the active area 1302 of the upper surface 104 of the semiconductor substrate 102 on which the BJT is formed and over the multi-depth isolation structure 1202. Furthermore, the single-depth isolation structure 1204 laterally encircles or encompasses a guardring area 1306 that is laterally between the isolation structures 1202, 1204. The guardring area 1306 laterally encircles or encompasses the multi-depth isolation structure 1202.

Referring to the photolithography mask 2402 of FIG. 24 (which is used to pattern the patterned photoresist 202 in FIG. 2), the opaque area 2404 may correspond to where the multi-depth isolation structure 1202 is formed to the second depth 1114 (e.g., where the second depth portion 1224 is formed). Referring to the photolithography mask 2422 (which is used to pattern the patterned photoresist 406 in FIG. 4), the opaque areas 2424, 2426, 2428 correspond to the active areas 1302, 1304 and guardring area 1306 of the semiconductor substrate 102.

Overlap of opaque areas and transparent areas of the photolithography masks 2402, 2422 may determine a depth to which a portion of a multi-depth trench is etched and to which the corresponding portion of the multi-depth isolation structure 1202 is formed. Opaque areas 2424, 2426, 2428 of the photolithography mask 2422 prevent a trench from being etched in corresponding areas of the semiconductor substrate 102, and hence, result in the active areas 1302, 1304 and guardring area 1306. Where a transparent area of the photolithography mask 2422 overlaps with a transparent area of the photolithography mask 2402, a trench portion to the first depth 1112 is etched, and hence, a resulting first depth portion 1222 of the multi-depth isolation structure 1202 is formed to the first depth 1112. Where a transparent area of the photolithography mask 2422 overlaps with an opaque area of the photolithography mask 2402, a trench portion to the second depth 1114 is etched, and hence, a resulting second depth portion 1224 of the multi-depth isolation structure 1202 is formed to the second depth 1114.

For example, at the cross-section 13-13 in the X-Z plane, lateral dimensions 2472 indicate where opaque areas 2424, 2426, 2428 of the photolithography mask 2422 result in the active areas 1302, 1304 and guardring area 1306. Lateral dimensions 2474 correspond to where transparent areas of the photolithography masks 2402, 2422 overlap and result in the first depth portion 1222 of the multi-depth isolation structure 1202. Lateral dimensions 2476 correspond to where transparent areas of the photolithography mask 2422 overlap with the opaque area 2404 of the photolithography mask 2402 and result in the second depth portion 1224 of the multi-depth isolation structure 1202.

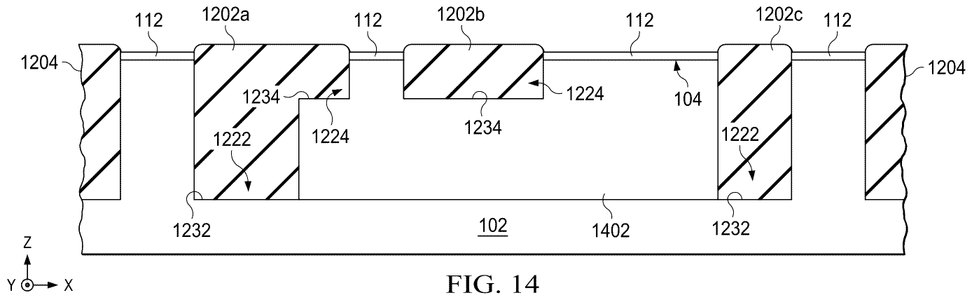

Referring to FIG. 14, a doped sub-collector diffusion region 1402 is formed in the semiconductor substrate 102 laterally within the multi-depth isolation structure 1202 (e.g., laterally between the first portion 1202a and the third portion 1202c). The doped sub-collector diffusion region 1402 may be formed by masking (e.g., by a photoresist using photolithography) areas of the semiconductor substrate 102 where a doped sub-collector diffusion region is not to be formed and implanting dopants into the semiconductor substrate 102. The doped sub-collector diffusion region 1402 extends from the upper surface 104 of the semiconductor substrate 102 into a depth in the semiconductor substrate 102. A concentration of dopants of the doped sub-collector diffusion region 1402 is greater than a concentration of the p-type dopant of the semiconductor substrate 102. In some examples, the doped sub-collector diffusion region 1402 is doped with an n-type dopant with a concentration in a range from 1×10¹⁸ cm⁻³ to 1×10²¹ cm⁻³. Another dopant and/or other doping concentrations may be implemented.

Although the semiconductor substrate 102 and doped sub-collector diffusion region 1402 are described herein as being doped with a certain dopant conductivity type, such components may be doped with an opposite conductivity type (e.g., being n-type doped instead of p-type doped, and vice versa) in other examples. Similarly, subsequently described components that are described as being doped with a certain dopant conductivity type may also be doped with an opposite conductivity type in other examples.

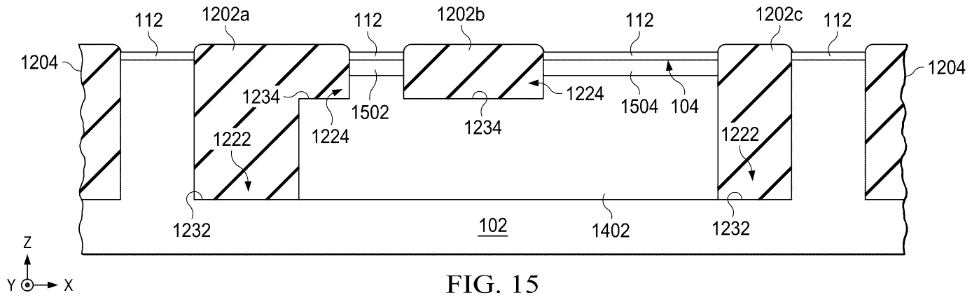

Referring to FIG. 15, a collector region 1502 and a collector contact region 1504 are formed in the semiconductor substrate 102. The collector region 1502 and collector contact region 1504 are formed in the doped sub-collector diffusion region 1402 in the semiconductor substrate 102. The collector region 1502 is laterally between the first portion 1202a and second portion 1202b of the multi-depth isolation structure 1202. The collector contact region 1504 is laterally between the second portion 1202b and third portion 1202c of the multi-depth isolation structure 1202. An implantation is performed to form the collector region 1502 and collector contact region 1504. The collector region 1502 and collector contact region 1504 may be formed by masking (e.g., by a photoresist using photolithography) the semiconductor substrate 102 and implanting a dopant into the semiconductor substrate 102 in respective exposed portions of the semiconductor substrate 102 corresponding to the collector region 1502 and collector contact region 1504. A concentration of the dopant of the collector region 1502 and collector contact region 1504 is greater than the concentration of the dopant of the doped sub-collector diffusion region 1402. The conductivity type of the dopant of the collector region 1502 and collector contact region 1504 is the same as the conductivity type of the dopant of the doped sub-collector diffusion region 1402. In some examples, the collector region 1502 and collector contact region 1504 are doped with an n-type dopant with a concentration in a range from 1×10²⁰ cm⁻³ to 1×10²¹ cm⁻³. Other doping concentrations may be implemented.

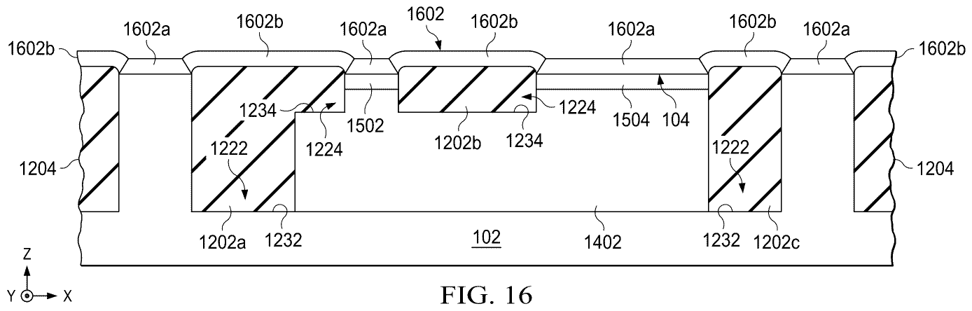

Referring to FIG. 16, the first mask layer 112 is removed, and a base layer 1602 is formed over the semiconductor substrate 102. The first mask layer 112 may be removed by an etch process selective to the material of the first mask layer 112 (e.g., preferentially etching or removing the materials of the first mask layer 112 over other materials), which etch process may be a wet etch process. The base layer 1602 includes a monocrystalline base layer 1602a and a polycrystalline base layer 1602b. The monocrystalline base layer 1602a and polycrystalline base layer 1602b together form the base layer 1602. In some examples, the base layer 1602 is or includes a semiconductor layer doped with a p-type dopant (e.g., an opposite conductivity type as the collector region 1502). In some examples, the base layer 1602 is or includes silicon germanium. In some examples, the base layer 1602 is doped with a p-type dopant with a concentration in a range from 1×10¹ cm⁻³ to 1×10²¹ cm⁻³. The base layer 1602 may also be doped with carbon (C) to prevent or reduce diffusion of the p-type dopant. The base layer 1602 may be epitaxially grown on the upper surface 104 of the semiconductor substrate 102 and over and on (e.g., adjoining) the isolation structures 1202, 1204. The base layer 1602 may be epitaxially grown by a non-selective epitaxial growth process in some examples. The non-selective epitaxial growth process grows the monocrystalline base layer 1602a from the upper surface 104 of the semiconductor substrate 102 (e.g., at the collector region 1502) and grows the polycrystalline base layer 1602b on other amorphous or polycrystalline surfaces, such as the isolation structures 1202, 1204. The monocrystalline base layer 1602a may meet the polycrystalline base layer 1602b at a facet that is not specifically illustrated. The non-selective deposition of the base layer 1602 forms the base layer 1602 conformally. The base layer 1602 may be in situ doped during the epitaxial growth process. The base layer 1602 (e.g., the monocrystalline base layer 1602a and polycrystalline base layer 1602b each) may further include multiple sub-layers, such as a nucleation sub-layer of the same material as the semiconductor substrate 102 at the upper surface 104, an undoped sub-layer, a doped sub-layer, and a cap sub-layer of the same material of the emitter layer (described subsequently). The epitaxial growth process may be a CVD process, such as low pressure CVD (LPCVD), reduced pressure CVD (RPCVD), metal-organic CVD (MOCVD), or the like. Other materials, dopant type, dopant concentration, and/or deposition process may be implemented.

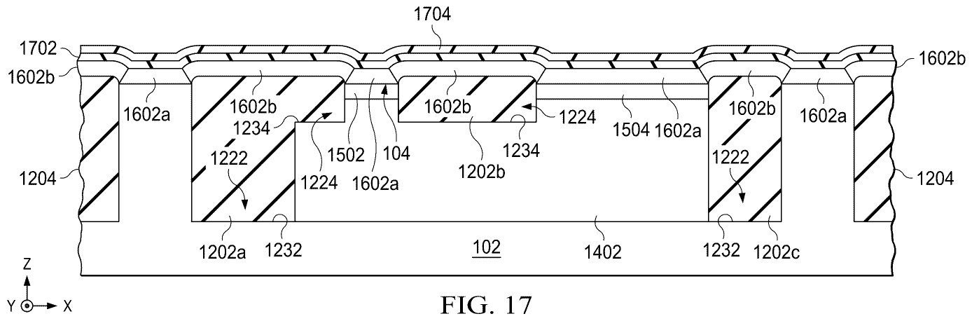

Referring to FIG. 17, a first dielectric spacer layer 1702 is formed conformally over the base layer 1602, and a second dielectric spacer layer 1704 is formed conformally over the first dielectric spacer layer 1702. In some examples, the second dielectric spacer layer 1704 is a dielectric material different from the dielectric material of the first dielectric spacer layer 1702. In some examples, the first dielectric spacer layer 1702 is silicon oxide (e.g., a TEOS oxide), and the second dielectric spacer layer 1704 is silicon nitride. The dielectric spacer layers 1702, 1704 may be deposited by CVD. Other dielectric materials and/or other deposition processes may be used in other examples.

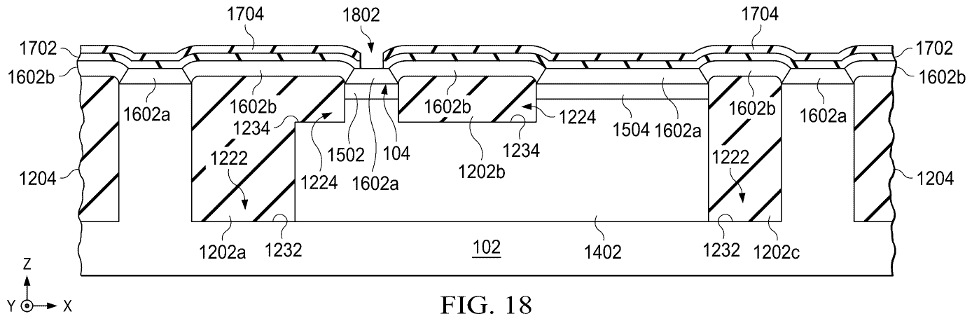

Referring to FIG. 18, the dielectric spacer layers 1702, 1704 are etched to form an emitter opening 1802 through the dielectric spacer layers 1702, 1704. The monocrystalline base layer 1602a (of the base layer 1602) is exposed through the emitter opening 1802. The dielectric spacer layers 1702, 1704 may be patterned using appropriate photolithography and etch (e.g., RIE) processes.

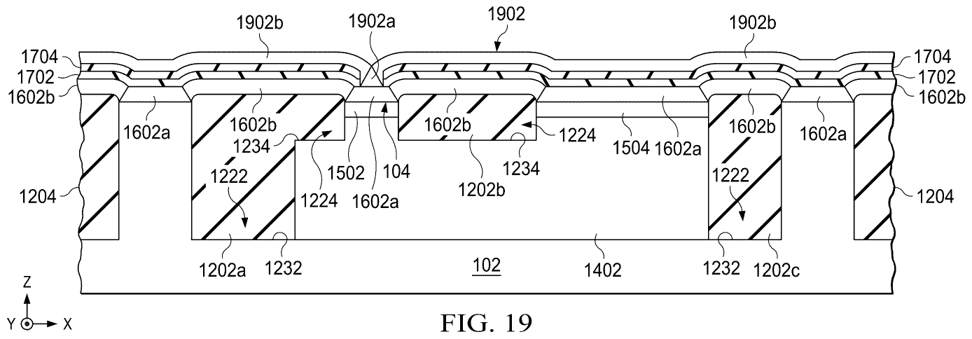

Referring to FIG. 19, an emitter layer 1902 is formed over the base layer 1602 (e.g., on the monocrystalline base layer 1602a). The emitter layer 1902 includes a monocrystalline emitter layer 1902a and a polycrystalline emitter layer 1902b. The monocrystalline emitter layer 1902a and polycrystalline emitter layer 1902b together form the emitter layer 1902. In some examples, the emitter layer 1902 is or includes a semiconductor layer doped with an n-type dopant (e.g., an opposite dopant type from the base layer 1602). In some examples, the emitter layer 1902 is or includes silicon. In some examples, the emitter layer 1902 is doped with an n-type dopant with a concentration in a range from 1×10¹⁹ cm⁻³ to 1×10²¹ cm⁻³. The emitter layer 1902 may be epitaxially grown on the base layer 1602 (e.g., the monocrystalline base layer 1602a) exposed through the emitter opening 1802 and on the second dielectric spacer layer 1704. The emitter layer 1902 may be epitaxially grown by a non-selective epitaxial growth process in some examples. The non-selective epitaxial growth process grows the monocrystalline emitter layer 1902a from the monocrystalline base layer 1602a and grows the polycrystalline emitter layer 1902b on other amorphous or polycrystalline surfaces, such as the second dielectric spacer layer 1704. The monocrystalline emitter layer 1902a may meet the polycrystalline emitter layer 1902b at a facet that is not specifically illustrated. The non-selective deposition of the emitter layer 1902 forms the emitter layer 1902 conformally. The emitter layer 1902 may be in situ doped during the epitaxial growth process. The epitaxial growth process may be a CVD process, such as LPCVD, RPCVD, MOCVD, or the like. Other materials, dopant type, dopant concentration, and/or deposition process may be implemented.

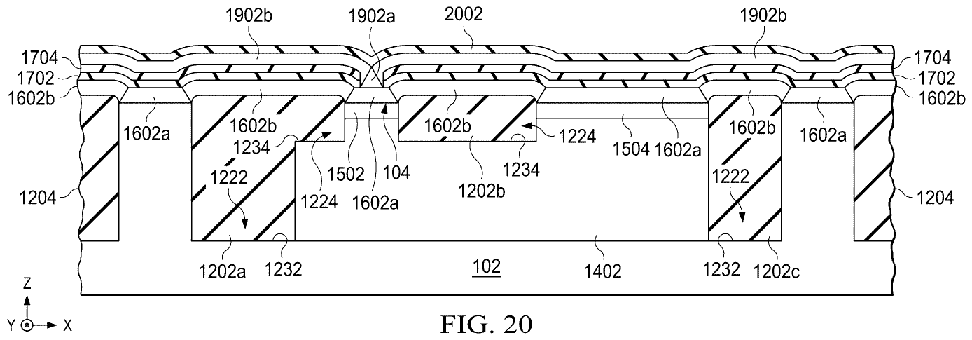

Referring to FIG. 20, an emitter dielectric cap layer 2002 is conformally formed over the emitter layer 1902. In some examples, the emitter dielectric cap layer 2002 is silicon oxide (e.g., a TEOS oxide) deposited by CVD, although other dielectric materials and/or other deposition processes may be used in other examples.

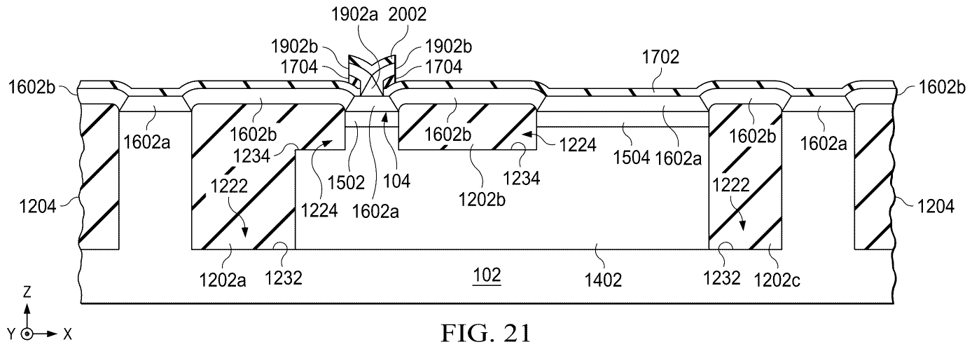

Referring to FIG. 21, the emitter dielectric cap layer 2002, polycrystalline emitter layer 1902b, and second dielectric spacer layer 1704 are patterned. In the illustrated example, the layers 2002, 1902b, 1704 are patterned using appropriate photolithography and etch (e.g., anisotropic etch, such as RIE) processes.

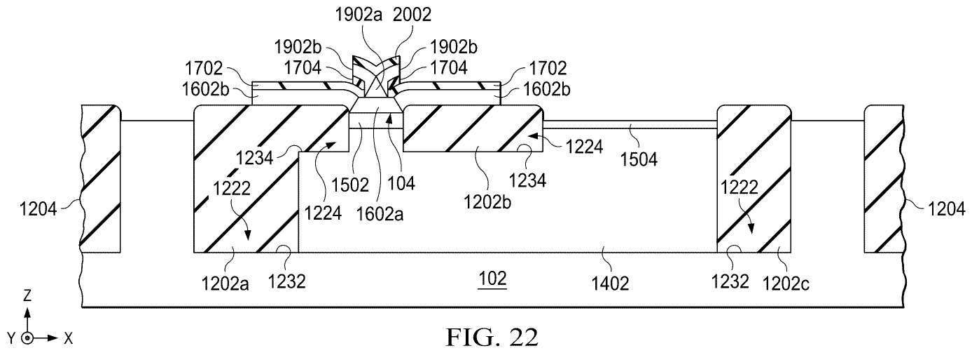

Referring to FIG. 22, the first dielectric spacer layer 1702 and the base layer 1602 (e.g., the polycrystalline base layer 1602b) are patterned. In some examples, patterning the base layer 1602 removes some of the monocrystalline base layer 1602a, such as laterally between the portions 1202b, 1202c of the multi-depth isolation structure 1202 and laterally between the isolation structures 1202, 1204, and further may etch some into the semiconductor substrate 102 where the monocrystalline base layer 1602a is removed. The first dielectric spacer layer 1702 and the polycrystalline base layer 1602b may be patterned using appropriate photolithography and etch (e.g., RIE) processes.

Referring to FIG. 23, metal-semiconductor compound 2302, 2304, 2306, 2308 are formed. The metal-semiconductor compound 2302 is on the emitter layer 1902 (e.g., the polycrystalline emitter layer 1902b and/or monocrystalline emitter layer 1902a). The metal-semiconductor compound 2304 is on the base layer 1602 (e.g., the polycrystalline base layer 1602b). The metal-semiconductor compound 2306 is on the semiconductor substrate 102 at the collector contact region 1504. The metal-semiconductor compound 2308 is on the semiconductor substrate 102 laterally between the isolation structures 1202, 1204. The metal-semiconductor compound 2302, 2304, 2306, 2308 may be a silicide (e.g., NiSix, TiSix, CoSix, PtSix), a germanicide, or the like.

To form the metal-semiconductor compound 2302, 2304, 2306, 2308, any remaining dielectric material on surfaces on which the metal-semiconductor compound 2302, 2304, 2306 are to be formed is removed. For example, the emitter dielectric cap layer 2002 and exposed portions of the first dielectric spacer layer 1702 may be removed by an etch and/or cleaning process. For example, when the emitter dielectric cap layer 2002 and the first dielectric spacer layer 1702 are silicon oxide, dilute hydrochloric acid (dHCl) may be used. The first dielectric spacer layer 1702 underlying the second dielectric spacer layer 1704 remains after the exposed portions of the first dielectric spacer layer 1702 are removed. Other layers and isolation structures may be thinned by the etch and/or cleaning process.

The metal-semiconductor compound 2302, 2304, 2306, 2308 may then be formed by depositing a metal (e.g., Ni, Ti, Co, Pt) over the semiconductor substrate 102, such as by physical vapor deposition (PVD), CVD, or the like. The metal is reacted with a semiconductor material, such as the semiconductor material of the emitter layer 1902 (e.g., polycrystalline emitter layer 1902b and/or monocrystalline emitter layer 1902a), the semiconductor material of the base layer 1602 (e.g., the polycrystalline base layer 1602b and/or monocrystalline base layer 1602a), and the semiconductor material of the semiconductor substrate 102. An anneal process may be used to cause the metal to react with a semiconductor material. For example, a laser anneal (e.g., a millisecond laser anneal) may be used in a reduced thermal budget implementation. Any unreacted metal may be removed, such as by an etch selective to the metal.

After forming the metal-semiconductor compound 2302, 2304, 2306, 2308, a dielectric layer 2312 is formed over the semiconductor substrate 102, and contacts 2322, 2324, 2326 are formed through the dielectric layer 2312. The dielectric layer 2312 may include one or more dielectric sub-layers. For example, the dielectric layer 2312 may include a conformal first dielectric sub-layer over the semiconductor substrate 102 and a second dielectric sub-layer over the first dielectric sub-layer. The conformal first dielectric sub-layer may be a stressor layer, an etch stop layer, or the like, which may be or include silicon nitride, silicon oxynitride, the like, or a combination thereof. The second dielectric sub-layer may be or include silicon oxide, silicon nitride, or the like. The dielectric layer 2312 may be or include a pre-metal dielectric (PMD), an inter-layer dielectric (ILD), or the like. The dielectric layer 2312 may be deposited using CVD, PECVD, atomic layer deposition (ALD), a combination thereof, or the like. The dielectric layer 2312 may be planarized, such as by a CMP.

The contacts 2322, 2324, 2326 extend through the dielectric layer 2312 and contact respective metal-semiconductor compound 2302, 2304, 2306. The contacts 2322, 2324, 2326 may each include one or more barrier and/or adhesion layers (e.g., titanium nitride (TiN), tantalum nitride (TaN), the like, or a combination thereof) conformally in a respective opening through the dielectric layer 2312, and a fill metal (e.g., tungsten (W), copper (Cu), aluminum (Al), the like, or a combination thereof) over and/or on the barrier and/or adhesion layer(s). To form the contacts 2322, 2324, 2326, respective openings may be formed through the dielectric layer 2312 to the metal-semiconductor compound 2302, 2304, 2306 using appropriate photolithography and etching processes. A metal(s) of the contacts 2322, 2324, 2326 are deposited in the openings through the dielectric layer 2312. The metal(s) may be deposited using an appropriate deposition process(es), such as CVD, PVD, or the like. Any excess metal(s) may be removed, such as by a CMP and/or by patterning using photolithography and etch processes.

FIG. 23 illustrates a semiconductor device 2300. The semiconductor device 2300 is or includes a BJT. The BJT includes the collector region 1502 in the semiconductor substrate 102, base layer 1602 (e.g., monocrystalline base layer 1602a and polycrystalline base layer 1602b), and emitter layer 1902 (e.g., monocrystalline emitter layer 1902a and polycrystalline emitter layer 1902b).

The collector region 1502 is in the semiconductor substrate 102 at the upper surface 104. The collector region 1502 is also in the doped sub-collector diffusion region 1402 in the semiconductor substrate 102. The base layer 1602 (e.g., the monocrystalline base layer 1602a) is over and on the collector region 1502, and the base layer 1602 (e.g., the polycrystalline base layer 1602b) is over and on an upper surface of the multi-depth isolation structure 1202 (e.g., portions 1202a, 1202b).

The multi-depth isolation structure 1202 (e.g., portions 1202a, 1202b) underlies the base layer 1602. The base layer 1602 (e.g., the polycrystalline base layer 1602b) adjoins the multi-depth isolation structure 1202 (e.g., portions 1202a, 1202b). The portions 1202a, 1202b of the multi-depth isolation structure 1202 extend laterally from the base layer 1602 (e.g., the polycrystalline base layer 1602b). For example, the first portion 1202a of the multi-depth isolation structure 1202 extends laterally away from a corresponding sidewall of the polycrystalline base layer 1602b (e.g., to the guardring area), and the second portion 1202b of the multi-depth isolation structure 1202 extends laterally away from a corresponding sidewall of the polycrystalline base layer 1602b to the collector contact region 1504.

The emitter layer 1902 (e.g., the monocrystalline emitter layer 1902a) is over and on the base layer 1602 (e.g., the monocrystalline base layer 1602a) and is through an opening defined by a spacer structure, and the emitter layer 1902 (e.g., the polycrystalline emitter layer 1902b) is over and on the spacer structure. The spacer structure includes the first dielectric spacer layer 1702 and the second dielectric spacer layer 1704.

The metal-semiconductor compound 2302 is on the emitter layer 1902 (e.g., the polycrystalline emitter layer 1902b and/or monocrystalline emitter layer 1902a). The metal-semiconductor compound 2304 is on the base layer 1602 (e.g., the polycrystalline base layer 1602b). The metal-semiconductor compound 2306 is on the upper surface 104 of the semiconductor substrate 102 on the collector contact region 1504.

In some examples, the BJT may be a heterojunction BJT. As indicated previously, in some examples, the collector region 1502 and the emitter layer 1902 may be silicon, and the base layer 1602 may include silicon germanium. Hence, in some examples, the base layer 1602 may include a semiconductor material dissimilar from respective semiconductor materials of the collector region 1502 and emitter layer 1902. The dissimilar semiconductor materials may form one or more heterojunctions in the BJT, and the BJT may therefore be a heterojunction BJT.

A lateral dimension of the second depth portion 1224 of the multi-depth isolation structure 1202 may differ between different examples. The lateral dimension, in this instance, is in a direction perpendicular to a direction from the collector region 1502 (e.g., corresponding to the active area 1302) to the collector contact region 1504 (e.g., corresponding to the active area 1304), which is perpendicular to the cross-section 13-13 in FIG. 24. In the illustrated example, the lateral dimension is in a y-direction. The lateral dimension of the second depth portion 1224 of the multi-depth isolation structure 1202 may be altered by changing a corresponding lateral dimension of the opaque area 2404 of the photolithography mask 2402. As shown in FIG. 24, the opaque area 2404 may be altered within a lateral dimension alteration range 2482, which results in a lateral dimension alteration range 2484 of the second depth portion 1224. Modifying the lateral dimension may tune a base-collector capacitance.

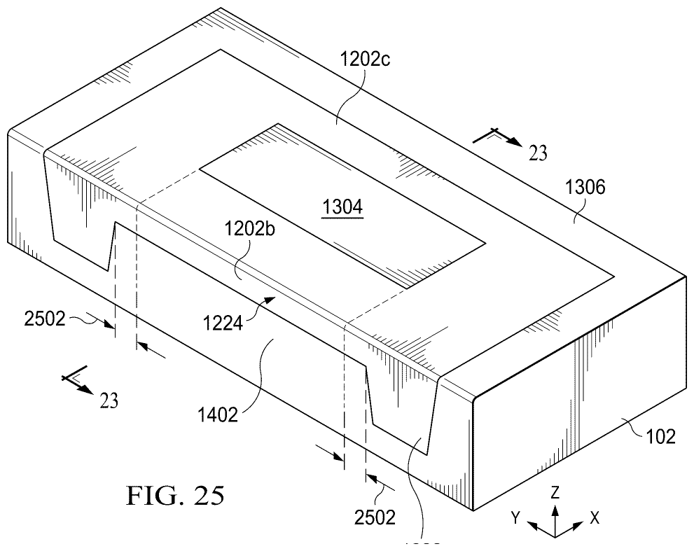

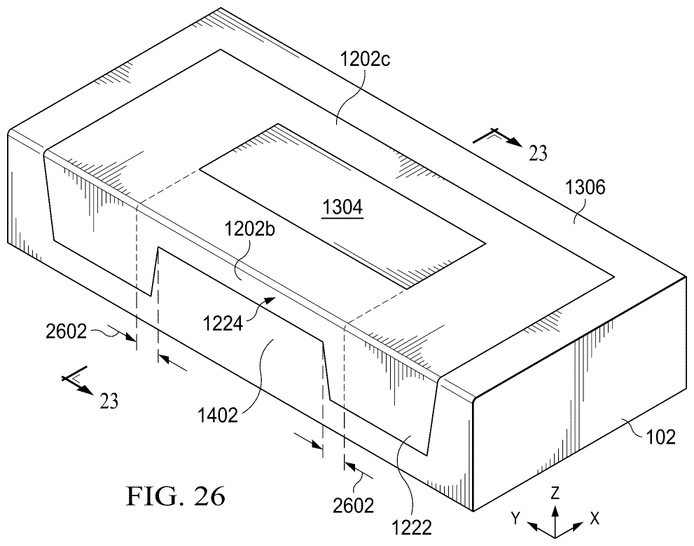

Hence, in some examples, the second depth portion 1224 may extend laterally (e.g., in a y-direction) from the active areas 1302, 1304, and in some examples, the active areas 1302, 1304 may extend laterally (e.g., in y-directions) from the second depth portion 1224. In some examples, respective boundaries of the second depth portion 1224 and the active areas 1302, 1304 may align along an x-direction. For example, FIGS. 25 and 26 illustrate perspective views of a portion of the semiconductor substrate 102 with the multi-depth isolation structure 1202. In FIG. 25, the second depth portion 1224 of the multi-depth isolation structure 1202 extends laterally (e.g., in y-directions) a lateral dimension 2502 from the active areas 1302, 1304. In FIG. 26, the active areas 1302, 1304 extend laterally (e.g., in y-directions) a lateral dimension 2602 from the second depth portion 1224 of the multi-depth isolation structure 1202. The base-collector capacitance in FIG. 26 may be less than a base-collector capacitance in FIG. 25.

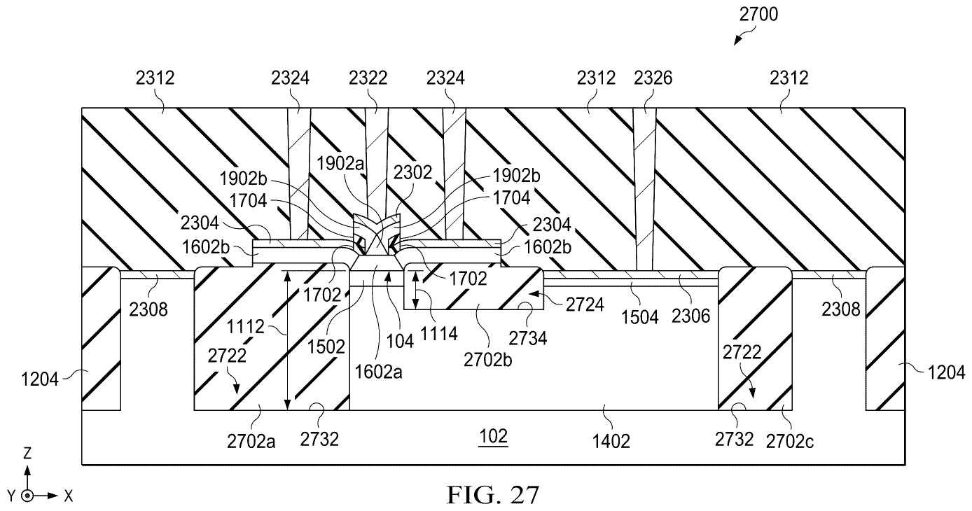

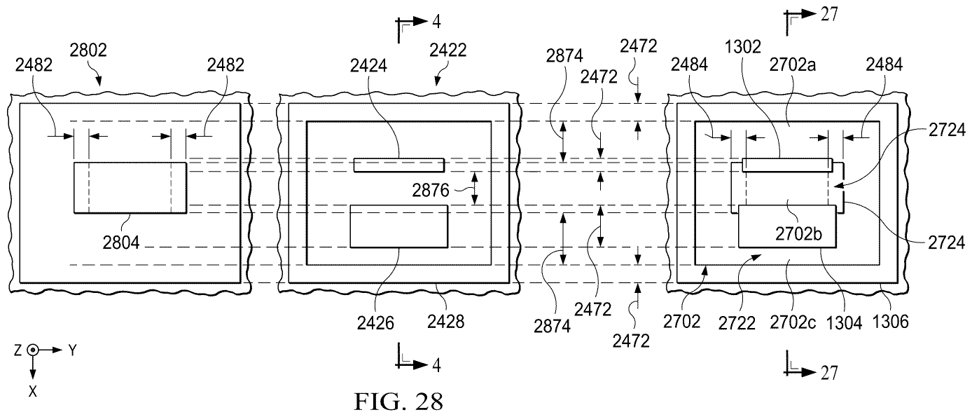

FIG. 27 is a cross-sectional view of a semiconductor device 2700 according to some examples. The semiconductor device 2700 is like the semiconductor device 2300 except that a multi-depth isolation structure 2702 (including portions 2702a, 2702b, 2702c) replaces the multi-depth isolation structure 1202. The semiconductor device 2700 may be formed using processing described above with respect to FIGS. 1 through 23 except a photolithography mask may be modified. FIG. 28 illustrates layout views of photolithography masks used in the method of manufacturing to achieve the semiconductor device 2700 of FIG. 27 and a corresponding layout of a portion of the semiconductor device 2700 according to some examples. X-Y-Z axes are illustrated in the figures for orientation of the various views. The photolithography mask 2402 of FIG. 24 that is used in FIG. 2 is replaced with the photolithography mask 2802 of FIG. 28 for the processing of FIG. 2. The photolithography mask 2802 includes an opaque area 2804, which corresponds to the patterned photoresist 202. Other areas of the photolithography mask 2802 are transparent. The photolithography mask 2422 is used for the processing of FIG. 4 as described above.

The multi-depth isolation structure 2702 includes a first depth portion 2722 that extends to the first depth 1112 and a second depth portion 2724 that extends to the second depth 1114. The first depth portion 2722 has a bottom surface 2732 at the first depth 1112. The second depth portion 2724 has a bottom surface 2734 at the second depth 1114. In the illustrated example, the first portion 2702a of the multi-depth isolation structure 2702 includes a part of the first depth portion 2722; the second portion 2702b of the multi-depth isolation structure 2702 includes a part of the second depth portion 2724; and the third portion 2702c of the multi-depth isolation structure 2702 includes a part of the first depth portion 2722.

FIG. 28 further shows a layout view (e.g., a composite view with the photolithography mask 2422 laterally relative to the photolithography mask 2802) of the multi-depth isolation structure 2702 and active areas of the semiconductor substrate 102. The layout of the multi-depth isolation structure 2702 shows a cross-section 27-27 that is the cross-section of FIG. 27. The multi-depth isolation structure 2702 laterally defines areas (e.g., active areas 1302, 1304) of the upper surface 104 of the semiconductor substrate 102 on which the BJT is to be formed. The multi-depth isolation structure 2702 laterally encircles or encompasses the active areas 1302, 1304 of the upper surface 104 of the semiconductor substrate 102 on which the BJT is to be formed. In the illustrated example, the second depth portion 2724 is laterally between the active areas 1302, 1304 and does not laterally encircle or encompass the active area 1302. The first depth portion 2722 laterally encircles or encompasses the second depth portion 2724 and the active areas 1302, 1304. Furthermore, the single-depth isolation structure 1204 laterally encircles or encompasses a guardring area 1306 that is laterally between the isolation structures 2702, 1204. The guardring area 1306 laterally encircles or encompasses the multi-depth isolation structure 2702.

Referring to the photolithography mask 2802 (which in this example is used to pattern the patterned photoresist 202 in FIG. 2), the opaque area 2804 may correspond to where the multi-depth isolation structure 2702 is formed to the second depth 1114 (e.g., where the second depth portion 2724 is formed). Referring to the photolithography mask 2422 (which is used to pattern the patterned photoresist 406 in FIG. 4), the opaque areas 2424, 2426, 2428 correspond to the active areas 1302, 1304 and guardring area 1306 of the semiconductor substrate 102.

Like described above, where a transparent area of the photolithography mask 2422 overlaps with a transparent area of the photolithography mask 2802, a trench portion to the first depth 1112 is etched, and hence, a resulting first depth portion 2722 of the multi-depth isolation structure 2702 is formed to the first depth 1112. Where a transparent area of the photolithography mask 2422 overlaps with an opaque area of the photolithography mask 2802, a trench portion to the second depth 1114 is etched, and hence, a resulting second depth portion 2724 of the multi-depth isolation structure 2702 is formed to the second depth 1114.

For example, at the cross-section 27-27 in the X-Z plane, lateral dimensions 2472 indicate where opaque areas 2424, 2426, 2428 of the photolithography mask 2422 result in the active areas 1302, 1304 and guardring area 1306. Lateral dimensions 2874 correspond to where transparent areas of the photolithography masks 2802, 2422 overlap and result in the first depth portion 2722 of the multi-depth isolation structure 2702. Lateral dimension 2876 corresponds to where a transparent area of the photolithography mask 2422 overlaps with the opaque area 2804 of the photolithography mask 2802 and results in the second depth portion 2724 of the multi-depth isolation structure 2702. A lateral dimension of the second depth portion 2724 of the multi-depth isolation structure 2702 may differ between different examples like described above with respect to FIGS. 25 and 26.

Although various examples have been described in detail, it should be understood that various changes, substitutions, and alterations can be made therein without departing from the scope defined by the appended claims.

What is claimed is:

1. A semiconductor device, comprising:
a semiconductor substrate;
a multi-depth isolation structure in the semiconductor substrate, the multi-depth isolation structure comprising:
a first isolation portion in the semiconductor substrate, the first isolation portion being to a first depth in the semiconductor substrate; and
a second isolation portion in the semiconductor substrate, the second isolation portion being to a second depth in the semiconductor substrate, the first depth being deeper in the semiconductor substrate than the second depth; and
a bipolar junction transistor (BJT) on the semiconductor substrate, the BJT including:
a collector region in the semiconductor substrate laterally between the first isolation portion and the second isolation portion; and
a base layer on the collector region and over and adjoining the first isolation portion and the second isolation portion.

2. The semiconductor device of claim 1, wherein the BJT further includes a collector contact region in the semiconductor substrate, the second isolation portion being laterally between the collector region and the collector contact region.

3. The semiconductor device of claim 2, wherein the multi-depth isolation structure laterally encompasses the collector region and the collector contact region.

4. The semiconductor device of claim 1, wherein the multi-depth isolation structure includes a first depth portion and a second depth portion, the first depth portion having a bottom surface at the first depth, the second depth portion having a bottom surface at the second depth, the first isolation portion including a part of the first depth portion, the first isolation portion and the second isolation portion including respective parts of the second depth portion, the second depth portion laterally encompassing the collector region.

5. The semiconductor device of claim 1, wherein the multi-depth isolation structure includes a first depth portion and a second depth portion, the first depth portion having a bottom surface at the first depth, the second depth portion having a bottom surface at the second depth, the first isolation portion including a part of the first depth portion, the second isolation portion including a part of the second depth portion, the second depth portion not laterally encompassing the collector region.

6. The semiconductor device of claim 1, wherein the BJT further includes an emitter layer on the base layer.

7. A method, comprising:
simultaneously etching a first trench portion of a trench to a first depth in a semiconductor substrate and a second trench portion of the trench to a second depth in the semiconductor substrate, the first depth being deeper in the semiconductor substrate than the second depth;
filling the trench with isolation material, the isolation material in the first trench portion forming a first isolation portion of an isolation structure, the isolation material in the second trench portion forming a second isolation portion of the isolation structure; and
forming a bipolar junction transistor (BJT) on the semiconductor substrate, at least a first portion of the BJT being laterally between the first isolation portion and the second isolation portion, at least a second portion of the BJT being over the first isolation portion and the second isolation portion.

8. The method of claim 7, wherein forming the BJT includes forming a collector region in the semiconductor substrate laterally between the first isolation portion and the second isolation portion.

9. The method of claim 8, wherein forming the BJT includes forming a collector contact region in the semiconductor substrate, the second isolation portion being laterally between the collector region and the collector contact region.

10. The method of claim 8, wherein the isolation structure laterally encompasses the collector region.

11. The method of claim 7, further comprising etching the first trench portion to an intermediate depth in the semiconductor substrate before simultaneously etching the first trench portion to the first depth and the second trench portion to the second depth.

12. The method of claim 7, wherein simultaneously etching the first trench portion to the first depth and the second trench portion to the second depth etches a first depth trench portion to the first depth and a second depth trench portion to the second depth, the first trench portion including respective parts of the first depth trench portion and the second depth trench portion, the second trench portion including a part of the second depth trench portion, the second depth trench portion laterally encompassing the first portion of the BJT.

13. The method of claim 7, wherein simultaneously etching the first trench portion to the first depth and the second trench portion to the second depth etches a first depth trench portion to the first depth and a second depth trench portion to the second depth, the first trench portion including a part of the first depth trench portion, the second trench portion including a part of the second depth trench portion, the second depth trench portion not laterally encompassing the first portion of the BJT.

14. The method of claim 7, wherein forming the BJT includes forming a base layer over and adjoining the first isolation portion and the second isolation portion.

15. A method, comprising:
forming a mask stack over a semiconductor substrate;
patterning a first layer of the mask stack using a first photolithography process and a first etch process;
patterning a second layer of the mask stack using a second photolithography process and a second etch process, the first layer being over the second layer, the second etch process further removing a portion of the first layer that is exposed using the second photolithography process;
etching a trench in the semiconductor substrate, the trench having a first trench portion and a second trench portion in the semiconductor substrate, the first trench portion corresponding to a first portion of the second layer exposed using the second photolithography process, the second trench portion corresponding to the portion of the first layer exposed using the second photolithography process;
filling the trench with isolation material, the isolation material in the first trench portion forming a first isolation portion, the isolation material in the second trench portion forming a second isolation portion; and
forming a bipolar junction transistor (BJT) on the semiconductor substrate, at least a first portion of the BJT being laterally between the first isolation portion and the second isolation portion, at least a second portion of the BJT being over the first isolation portion and the second isolation portion.

16. The method of claim 15, wherein the second etch process removes the portion of the first layer exposed using the second photolithography process and etches the second layer where the portion of the first layer is removed, wherein following the second etch process, an opening is through the second layer corresponding to the first portion of the second layer exposed using the second photolithography process, and a second portion of the second layer remains corresponding to where the portion of the first layer is removed by the second etch process.

17. The method of claim 16, further comprising etching a third layer and a fourth layer forming an opening through the third layer and the fourth layer corresponding to the opening through the second layer, wherein the mask stack further includes the third layer and the fourth layer, the second layer being over the third layer, the third layer being over the fourth layer, the fourth layer being over the semiconductor substrate, wherein etching the fourth layer further removes the second portion of the second layer.

18. The method of claim 17, wherein etching the trench in the semiconductor substrate includes:
etching an intermediate trench to an intermediate depth in the semiconductor substrate through the opening through the third layer and the fourth layer, wherein etching the intermediate trench further removes a portion of the third layer corresponding to the second portion of the second layer forming a laterally expanded opening through the third layer; and
etching the semiconductor substrate through the laterally expanded opening to extend the intermediate trench to the trench.

19. The method of claim 15, wherein etching the trench in the semiconductor substrate includes etching a first depth trench portion and a second depth trench portion, the first depth trench portion being to a first depth in the semiconductor substrate, the second depth trench portion being to a second depth in the semiconductor substrate, the first depth being deeper in the semiconductor substrate than the second depth, the second depth trench portion corresponding to the portion of the first layer exposed using the second photolithography process.

20. The method of claim 19, wherein the first trench portion and the second trench portion each include respective portions of the second depth trench portion, the second depth trench portion laterally encompassing the first portion of the BJT.

21. The method of claim 19, wherein the second trench portion includes a portion of the second depth trench portion, the second depth trench portion not laterally encompassing the first portion of the BJT.
